(19) United States
(12) Patent Application Publication
(10) Pub. No.: US 2024/0038631 A1
(43) Pub. Date: Feb. 1, 2024

(54) THREE-DIMENSIONAL INTEGRATED CIRCUIT MODULE AND FABRICATION METHOD THEREFOR

(71) Applicant: WUHAN XINXIN SEMICONDUCTOR MANUFACTURING CO., LTD., Wuhan, Hubei (CN)

(72) Inventors: Sheng HU, Wuhan, Hubei (CN); Jun ZHOU, Wuhan, Hubei (CN); Peng SUN, Wuhan, Hubei (CN); Qiong ZHAN, Wuhan, Hubei (CN)

(21) Appl. No.: 18/275,536

(22) PCT Filed: May 28, 2021
(86) PCT No.: PCT/CN2021/097007

§ 371 Date: Aug. 2, 2023

(30) Foreign Application Priority Data
Apr. 26, 2021 (CN) 202110455072.5

(51) Int. Cl. H01L 23/46; H01L 23/528; H01L 23/50; H01L 23/498; H01L 21/48

(52) U.S. Cl. CPC H01L 23/46; H01L 23/5283; H01L 23/50; H01L 23/49811; H01L 21/4853

(57) ABSTRACT

A three-dimensional (3D) integrated circuit (IC) module and a method of fabricating the 3D IC module are disclosed. In the 3D IC module, a conductive hole for connection with an internal specified metal layer and a trench arranged to avoid the conductive hole are formed in a topmost substrate of a semiconductor structure. A first passivation layer spans over and covers the trench, the first passivation layer and the trench together delimit a heat exchange channel. During operation of 3D IC module, a heat dissipation medium may be caused to flow through the heat exchange channel to facilitate heat dissipation. Thus, the 3D IC module has enhanced heat dissipation ability and is substantially immune from the problems of excessive heat build-up and uneven heat dissipation. This helps optimize performance and reliability of the 3D IC module. The method can be used to make such a 3D IC module.

### TECHNICAL FIELD

The present invention relates to the field of integrated circuit (IC) technology and, in particular, to a three-dimensional (3D) IC module and a method of fabricating such a 3D IC module.

### BACKGROUND

The boom of the electronics industry provides a main driving force for the evolution of the contemporary packaging technology. Main pursuits of advanced packaging are increased miniaturization, higher density, operation at higher frequencies and higher speeds, higher performance, higher reliability and lower cost, and system-in-packages (SiPs) is one of the most important techniques with the greatest potential to meet these high-density system integration demands. As a powerful and compact system, a SiP is a three-dimensional (3D) integrated circuit (IC) module obtained by integrating and assembling active components, passive components, MEMS devices or discrete chips (e.g., photoelectric chips, biological chips, memory chips, logic chips, computing chips), which have different functions or are fabricated by different processes. For example, some 3D IC modules used in a number of emerging applications (e.g., edge computing, artificial intelligence) are system-on-chip (SoC) products, which include 3D integrated logic and memory chips and thus possess both the high-speed computing ability of logic chips and high-speed storage ability of memory chips.

Despite their excellent performance per unit area achieved by SiP technology, those 3D IC modules tend to suffer from inadequate heat dissipation due to high power consumption per unit area. For example, in edge computing or artificial intelligence applications, logic chips consume much power due to extremely high computational burden, contributing to total power of the modules which may be as high as 100 or more watts. Uneven heat dissipation is another challenge. Extreme heat generation and uneven heat dissipation will lead to degradations in chip performance and reliability. For example, a DRAM chip in a module may have an unstable refresh rate due to extreme heat generated by a logic chip incorporated in the same module.

### SUMMARY OF THE INVENTION

The present invention provides a 3D IC module with enhanced heat dissipation ability, as well as a method of fabricating such a 3D IC module.

In one aspect, the present invention provides a three-dimensional (3D) integrated circuit (IC) module including a semiconductor structure and a first passivation layer on the semiconductor structure. The semiconductor structure includes at least two substrates which are stacked vertically one on another and electrically connected to one another. Additionally, the semiconductor structure includes at least one conductive hole located in a topmost one of the substrates and configured for connection with an internal specified metal layer. In the topmost substrate in the semiconductor structure, a trench arranged to avoid the conductive hole is also formed, and the first passivation layer spans over and covers the trench to define a heat exchange channel.

Optionally, the heat exchange channel may include at least one heat dissipation medium inlet and at least one heat dissipation medium outlet, which are configured to allow a heat dissipation medium to be introduced to the heat exchange channel through the heat dissipation medium inlet and discharged therefrom through the heat dissipation medium outlet, the heat dissipation medium inlet provided in a side face and/or an upper surface of the semiconductor structure, the heat dissipation medium outlet provided in a side face and/or the upper surface of the semiconductor structure.

Optionally, the topmost substrate may include a substrate layer and an interconnect layer underlying the substrate layer, wherein the specified metal layer is situated within the interconnect layer, and the conductive hole extends through the substrate layer, with a bottom surface located within the interconnect layer.

Optionally, a bottom surface of the heat exchange channel may be located within the substrate layer.

Optionally, the conductive hole may include a pad metal layer, which extends from the inside of the conductive hole over an upper surface of the first passivation layer.

Optionally, the 3D IC module may further include a second passivation layer on the first passivation layer, wherein a portion of the pad metal layer is defined by and exposed from the second passivation layer to serve as a pad.

Optionally, the upper surface of the semiconductor structure may include a heat exchange region for accommodating the heat exchange channel and a plurality of electrical connection regions for accommodating a set of conductive holes and pads, wherein the heat exchange region interlaces with the plurality of electrical connection regions, or the electrical connection regions are all disposed around the heat exchange region.

In another aspect, the present invention provides a method of fabricating a 3D IC module, including the steps of:
providing a semiconductor structure including at least two substrates, which are stacked vertically one on another and electrically connected to one another;
performing a downward etching process on a topmost one of the substrates to form at least one contact hole and a trench, which are both open upwardly, the trench arranged to avoid the contact hole, the contact hole configured to establish an electrical connection with a specified metal layer within the semiconductor structure, the trench configured to provide a heat exchange channel, wherein a depth of the contact hole is controlled so that the specified metal layer is exposed or not;
forming a first passivation layer on the semiconductor structure, which covers an upper surface of the topmost substrate and spans over and covers the trench so that the first passivation layer covering the trench to define the heat exchange channel;
removing the first passivation layer above and within the contact hole and causing exposure of the specified metal layer through the contact hole; and
forming a pad metal layer on the semiconductor structure, a portion of the pad metal layer in the contact hole is electrically connected to the specified metal layer, thereby forming a conductive hole.

Optionally, the topmost substrate may include a substrate layer and an interconnect layer underlying the substrate layer, wherein the specified metal layer is situated within the interconnect layer, and the conductive hole extends through the substrate layer with a bottom surface located within the interconnect layer.

Optionally, a depth of the trench may be smaller than or equal to the depth of the contact hole.

Optionally, the method may further include, after the contact hole and the trench are formed and before the first passivation layer is formed, conformally forming a surface cap layer over the semiconductor structure, which covers inner surfaces of the contact hole and the trench but does not fill up the trench, wherein after the first passivation layer is etched and before the pad metal layer is formed, the surface cap layer on a bottom surface of the contact hole is at least partially removed, thereby causing the exposure of the specified metal layer through the contact hole.

Optionally, the method may further include:
forming a second passivation layer over the semiconductor structure, which covers the first passivation layer and the pad metal layer; and
etching the second passivation layer so that a portion of the pad metal layer is exposed from the second passivation layer to serve as a pad.

In the 3D IC module of the present invention, the conductive hole for connection with the internal specified metal layer and the trench arranged to avoid the conductive hole are formed in the topmost substrate of the semiconductor structure. Moreover, the first passivation layer spans over and covers the trench so that the first passivation layer covering the trench to define the heat exchange channel. During operation of 3D IC module, a heat dissipation medium may be caused to flow through the heat exchange channel to facilitate heat dissipation. Thus, the 3D IC module has enhanced heat dissipation ability and is substantially immune from the problems of excessive heat build-up and uneven heat dissipation. This helps optimize performance and reliability of the 3D IC module.

In the method of the present invention, the at least one contact hole and the trench arranged to avoid the contact hole are first formed in the topmost substrate of the semiconductor structure, and the first passivation layer is then formed on the semiconductor structure so as to cover the upper surface of the semiconductor structure and span over the trench. In this way, the first passivation layer covers the trench to define the heat exchange channel. After that, the first passivation layer is etched, and exposure of the specified metal layer in the semiconductor structure is caused through the contact hole. The portion of the pad metal layer in the contact hole is electrically connected to the specified metal layer, thereby forming the conductive hole. In this method, during the formation of the conductive hole in the semiconductor structure, the heat exchange channel for enhancing heat dissipation is simultaneously formed, making the fabrication easier without causing a significant increase in cost. As the heat exchange channel is routed on the top of the semiconductor structure 100 off the conductive hole, it will not expand the size of the module. During operation of the 3D IC module, a heat dissipation medium may be continuously supplied to and discharged from the heat exchange channel to provide heat exchange.

### BRIEF DESCRIPTION OF THE DRAWINGS

FIG. 1 is a schematic flowchart of a method of fabricating a 3D IC module according to an embodiment of the present invention.

FIG. 2 is a schematic cross-sectional view of a semiconductor structure to be processed in a method of fabricating a 3D IC module according to an embodiment of the present invention.

FIG. 3A is a schematic cross-sectional view of a semiconductor structure after a contact hole and a trench are formed in a method of fabricating a 3D IC module according to an embodiment of the present invention.

FIG. 3B is a schematic plan view of a semiconductor structure after a contact hole and a trench are formed in a method of fabricating a 3D IC module according to an embodiment of the present invention.

FIG. 3C is a schematic plan view of a semiconductor structure after a contact hole and a trench are formed in a method of fabricating a 3D IC module according to an embodiment of the present invention.

FIG. 4 is a schematic cross-sectional view of a semiconductor structure after a first passivation layer is formed in a method of fabricating a 3D IC module according to an embodiment of the present invention.

FIG. 5 is a schematic cross-sectional view of a semiconductor structure after a first passivation layer is etched in a method of fabricating a 3D IC module according to an embodiment of the present invention.

FIG. 6 is a schematic cross-sectional view of a semiconductor structure after a pad metal layer is formed in a method of fabricating a 3D IC module according to an embodiment of the present invention.

FIG. 7A is a schematic cross-sectional view of a semiconductor structure after a second passivation layer and a pad are formed in a method of fabricating a 3D IC module according to an embodiment of the present invention.

FIG. 7B is a schematic plan view of a semiconductor structure after a second passivation layer and pads are formed in a method of fabricating a 3D IC module according to an embodiment of the present invention.

In these figures:
100—semiconductor structure; 10—first substrate; 20—second substrate; 21—specified metal layer; 110—contact hole; 120—trench; 101—protective layer; 102—surface cap layer; 103—first passivation layer; 104—pad metal layer; 105—second passivation layer; 104a—pad; 120a—heat exchange channel; 110a—conductive hole.

### DETAILED DESCRIPTION

Three-dimensional (3D) integrated circuit (IC) modules and methods of fabrication proposed in the present invention will be described in detail below with reference to the accompanying drawings and to specific embodiments. Advantages and features of the invention will become more apparent from the following description. It will be understood that the figures are provided in a very simplified form not necessarily drawn to exact scale for the only purpose of facilitating easy and clear description of the disclosed embodiments.

It is to be noted that, the terms “first”, “second” and the like may be used hereinafter to distinguish between similar elements without necessarily implying any particular ordinal or chronological sequence. It will be understood that the terms so used are interchangeable under appropriate circumstances such that the embodiments of the invention described herein are, for example, capable of operation in sequences other than those illustrated or otherwise described herein. Similarly, if a method is described herein as including a series of steps, the order of such steps as presented herein is not necessarily the only order in which such steps may be performed, and certain steps of the stated steps may possibly be omitted and/or certain other steps not described herein may possibly be added to the method. It will be understood, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

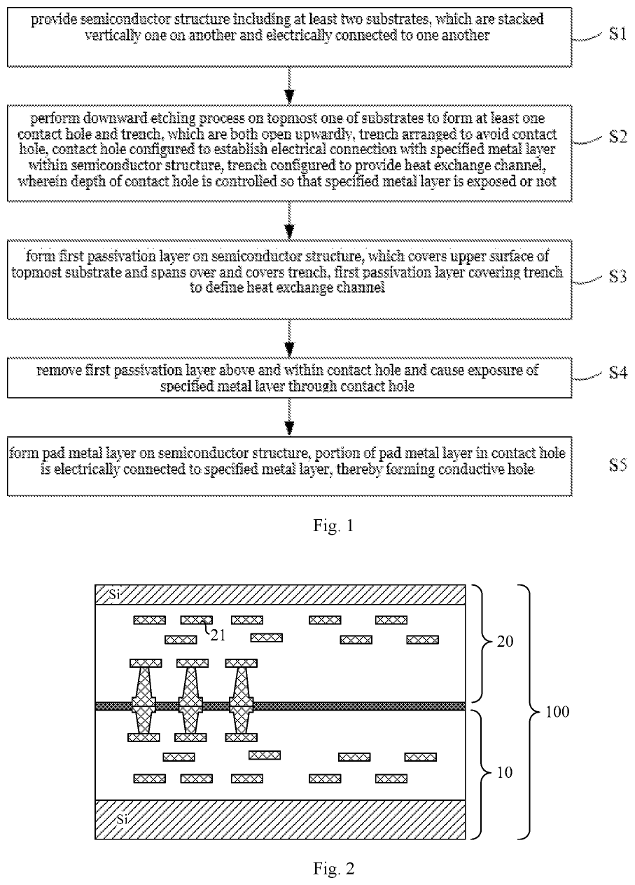

FIG. 1 is a schematic flowchart of a method of fabricating a 3D IC module according to an embodiment of the present invention. Referring to FIG. 1, the method of fabricating a 3D IC module according to an embodiment of the present invention includes the steps of:
S1: providing a semiconductor structure, the semiconductor structure includes at least two substrates, which are stacked vertically one on another and electrically connected to one another;
S2: performing a downward etching process on a topmost one of the substrates to form at least one contact hole and a trench, which are both open upwardly, the trench is arranged to avoid the contact hole, the contact hole is configured to establish an electrical connection with a specified metal layer within the semiconductor structure, the trench is configured to provide a heat exchange channel, wherein a depth of the contact hole is controlled so that the specified metal layer is exposed or not;
S3: forming a first passivation layer over the semiconductor structure, which covers an upper surface of the topmost substrate and spans over and covers the trench to define the heat exchange channel;
S4: removing the first passivation layer above and within the contact hole and causing exposure of the specified metal layer through the contact hole; and
S5: forming a pad metal layer on the semiconductor structure, a portion of the pad metal layer in the contact hole is electrically connected to the specified metal layer, thereby forming a conductive hole.

A specific embodiment of the above method of fabricating a 3D IC module will be described below with reference to the other accompanying drawings.

FIG. 2 is a schematic cross-sectional view of a semiconductor structure to be processed in the method of fabricating a 3D IC module according to an embodiment of the present invention. Referring to FIG. 2, in step S1 of the method of fabricating a 3D IC module, a semiconductor structure 100 is provided, the semiconductor structure 100 includes at least two substrates, which are stacked vertically one on another and electrically connected to one another.

In particular, the semiconductor structure 100 may be a 3D laminated structure obtained using a 3D integration and assembly technique. In the 3D integration and assembly technique, active components, passive components, MEMS devices or discrete chips (e.g., photoelectric chips, biological chips, memory chips, logic chips, computing chips) of different functions and fabricated using different processes along a 3D direction (e.g., an X, Y or Z direction in an orthogonal coordinate system) are assembled into a complete circuit system. Depending on design requirements, a varying number of devices (or chips) may be integrated in the semiconductor structure 100. In embodiments of the present invention, the semiconductor structure 100 provided in step S1 includes at least two substrates stacked vertically one on another. Here, the “substrates” refer to semiconductor substrates separately obtained from individual processes. Each of the substrates may include a substrate layer (e.g., silicon substrate, SOI substrate or another suitable substrate), as well as fabricated on the basis of the substrate layer, semiconductor devices, interconnect layers, passivation layers and the like (referred to as a dielectric layer). In order to form the semiconductor structure 100, the substrates may be stacked together by gluing, bonding or otherwise. For example, they may be glued or bonded together with the substrate layers being adjacent to each other or opposite to each other (as shown in FIG. 2). Alternatively, the substrate layer of one substrate may be glued or bonded to the dielectric layer of another substrate. The gluing or bonding may be accomplished according to any suitable method known in the art. In addition, in order to interconnect the substrates in the semiconductor structure 100, an interconnection method such as through-silicon via (TSV) or rewiring may be employed in the 3D integration and assembly technique to electrically interconnect the substrates before, during or after the stacking of the multiple substrates. The interconnection method may be any suitable method known in the art. Further, after the substrates are interconnected, the substrate(s) that provide(s) an upper surface and/or a lower surface of the laminated structure may be thinned, or the substrate layers of some substrates may be even stripped away, as required. Therefore, some substrates in the semiconductor structure 100 provided in step S1 may not have a substrate layer.

The following embodiments are set forth in the context of the semiconductor structure integrating two substrates along the direction perpendicular to surfaces of the substrate, as an example. As shown in FIG. 2, in one embodiment, the semiconductor structure 100 provided in step S1 includes a first substrate 10 and a second substrate 20, which are stacked from the bottom upward. That is, the second substrate 20 is located on the top of the semiconductor structure 100. The first substrate 10 and the second substrate 20 may contain chips or devices of various types, and depending on circuit system design requirements of the 3D IC module, each of the first substrate 10 and the second substrate 20 in the semiconductor structure 100 may contain one or more chips (or devices). The interconnection of the first substrate 10 and the second substrate 20 allows the semiconductor structure 100 to contain one, two or more functional units (e.g., memory units, computing units, etc.). As an example, the first substrate 10 may include a memory chip such as, for example, a dynamic random access memory (DRAM) chip, and the second substrate 20 may include a logic chip (or logic device).

Referring to FIG. 2, in each of the first substrate 10 and the second substrate 20, an interconnect layer including interconnect metal layers and through-silicon vias (TSVs) (represented by the boxes filled with cross lines in the figure) may be formed. During or after the bonding process, as needed, the interconnect layers in the first substrate 10 and the second substrate 20 may be electrically connected to each other, thereby forming an interconnect system within the semiconductor structure 100, which provides interconnection between the first substrate 10 and the second substrate 20. As part of the interconnect system, at least one specified metal layer 21 is formed in the semiconductor structure (in this embodiment, for example, in the upper second substrate 20). The specified metal layer 21 is intended to be electrically connected to the outside of the semiconductor structure 100, the specified metal layer 21 enables the provision of a power supply for the devices (or chips) within the semiconductor structure 100, as well as transmission and reception of signals to or from the devices (or chips) in the semiconductor structure 100. The location where the specified metal layer 21 is electrically led out depends on design requirements of the module. In this embodiment, for example, the 3D IC module being fabricated may require the fabrication of a pad on the second substrate 20, which is to be electrically connected to the specified metal layer 21 in the semiconductor structure 100. Moreover, in order to make the fabrication of the pad easier and to enhance heat dissipation, the substrate layer of the second substrate may be thinned to a thickness of about 1 μm to 50 μm. An upper surface of the second substrate 20 provides an upper surface of the semiconductor structure 100 and, for example, may have a rectangular shape with a side length of about 3 mm to 50 mm.

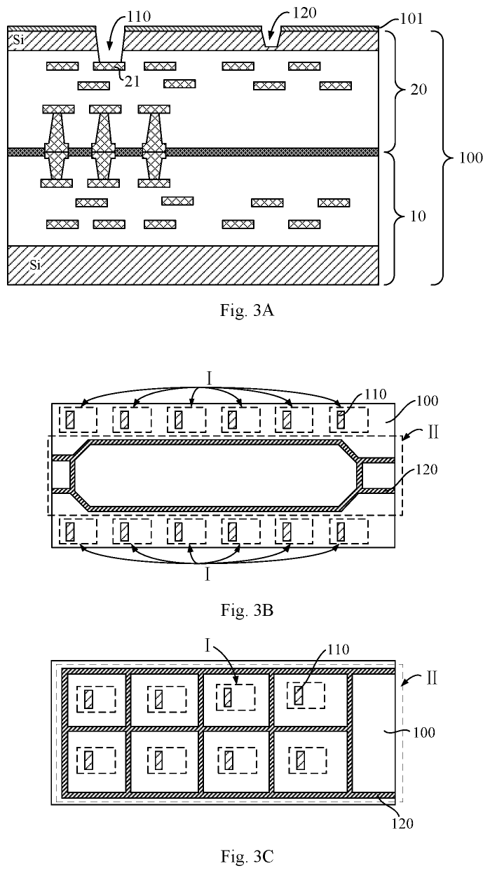

FIG. 3A is a schematic cross-sectional view of the semiconductor structure after a contact hole and a trench are formed in the method according to an embodiment of the present invention. Referring to FIG. 3A, the method of fabricating a 3D IC module includes the step S2, a downward etching process is performed on a topmost one of the substrates (in this embodiment, the process proceeds downwards from the upper surface of the second substrate 20), forming at least one contact hole 110 which is open upwardly and a trench 120 which is open upwardly and arranged to avoid the contact hole 110. The contact hole 110 is configured to establish an electrical connection with the specified metal layer 21 in the semiconductor structure, and trench 120 is configured to provide a heat exchange channel, wherein a depth of the contact hole 110 is controlled so that the specified metal layer 21 is exposed or not.

In this embodiment, a conductive hole for electrically leading out the specified metal layer 21 in the semiconductor structure 100 is to be formed in the contact hole 110, and a heat dissipation medium (e.g., liquid or gas) is to be introduced in the heat exchange channel provided by the trench 120 arranged to avoid the contact hole 110 during operation of the 3D IC module to enhance heat dissipation. It is unnecessary for the trench 120 to be connected to any conductive component, and in order to avoid adversely affecting the interconnect system in the semiconductor structure 100, it is preferred that no conductive component in semiconductor structure 100 is exposed in the trench 120.

In step S2, before the second substrate 20 is etched, a protective layer 101 may be formed on the second substrate 20. The protective layer 101 may include silicon oxide, silicon nitride, silicon oxynitride or a layer stack thereof. In the etching process on the second substrate 20, the protective layer 101 may serve as a hard mask layer. Patterns for the contact hole 110 and the trench 120 may be formed in a single photolithography step, or in two separate photolithography steps. Preferably, they are formed in a single photolithography and etching process. In particular, the process may include: at first, coating a photoresist layer on the protective layer 101 and patterning the photoresist layer by exposing with a single photomask and developing the photoresist layer; next, with the patterned photoresist layer serving as a mask, etching and patterning the protective layer 101; and then removing the photoresist layer and, with the patterned protective layer 101 serving as a mask, etching the second substrate 20 to form therein the contact hole 110 and the trench 120.

The contact hole 110 and the trench 120 are formed by performing the downward etching process performed on the topmost substrate (in this embodiment, the second substrate 20), the contact hole 110 and the trench 120 are both upwardly open. The distance between an upper surface of the topmost substrate (in this embodiment, an upper surface of the protective layer 101) and a bottom surface of the contact hole 110 is taken as the depth of the contact hole 110, and the distance between the upper surface of the topmost substrate and a bottom surface of the trench 120 is taken as a depth of the trench 120. Referring to FIG. 3A, in this embodiment, the upper second substrate 20 includes a substrate layer and an interconnect layer underlying the substrate layer, and the specified metal layer 21 is located within the interconnect layer. The depth of the contact hole 110 may be controlled so that the contact hole 110 extends through the substrate layer of the second substrate 20, with its bottom surface being situated within the interconnect layer, so that the specified metal layer 21 within the underlying interconnect layer is partially exposed. However, the present invention is not so limited, because the contact hole 110 may be so formed in step S2 so to extend though only the substrate layer of the second substrate 20, or optionally additionally through part of the thickness of the interconnect layer. In this case, the material of the interconnect layer between the bottom surface of the contact hole 110 and the specified metal layer 21 may be subsequently etched away. In this way, the depth of the contact hole 110 can be controlled so that the specified metal layer 21 is exposed or not.

In this embodiment, both the contact hole 110 and the trench 120 formed in step S2 are TSV holes. The depth of the trench 120 may be equal to the depth of the contact hole 110, or not. For example, the depth of the trench 120 may be smaller than the depth of the contact hole 110. The depths of the trench 120 and the contact hole 110 may be in the range of about 5 μm to 10 μm. In the example shown in FIG. 3A, the contact hole 110 extends through the substrate layer of the second substrate 20, while the trench 120 does not extend through the substrate layer of the second substrate 20 (i.e., the depth of the trench 120 is smaller than the thickness of the substrate layer in the second substrate 20). However, the present invention is not so limited. In other embodiments, the trench 120 may alternatively extend through the substrate layer in the second substrate 20, exposing the underlying dielectric layer.

In this embodiment, a first passivation layer is subsequently formed so as to span over and cover the trench 120 to define the heat exchange channel. Therefore, the trench 120 may be designed to have a narrow width (a dimension measured in a plane parallel to the second substrate 20 along a direction perpendicular to the extension direction of the trench 120), for example, in the range of approximately 0.3 μm to 100 μm. The contact hole 110 may, for example, have a circular, elliptical or polygonal cross-section along the plane parallel to the second substrate 20. The width of the trench 120 in the plane parallel to the second substrate 20 may be configured to be smaller than a maximum opening size of the contact hole 110.

In some embodiments, the semiconductor structure 100 may require two or more pads configured for connection with the same specified metal layer or different specified metal layers in the semiconductor structure 100. In this case, as many contact holes 110 as the pads may be formed in step S2. The trench 120 that provides the heat exchange channel may be composed of multiple sections extending in different regions so as to come into communication with one another, or include multiple sections extending in different regions so as not to come into communication with one another. At least one heat dissipation medium inlet and at least one heat dissipation medium outlet (not shown) may be provided at terminal ends of the trench 120. A heat dissipation medium may be introduced into the heat exchange channel through the heat dissipation medium inlet and discharged therefrom through the heat dissipation medium outlet. Either of the heat dissipation medium inlet and the heat dissipation medium outlet may be arranged on a side face of the second substrate 20. However, the present invention is not so limited. Either of the heat dissipation medium inlet and the heat dissipation medium outlet may be alternatively arranged at a side face location of the semiconductor structure 100 above or below a plane of the trench 120. Still alternatively, either of the heat dissipation medium inlet and the heat dissipation medium outlet may be arranged on the upper or lower surface of the semiconductor structure 100.

The upper surface of the semiconductor structure 100 may define a heat exchange region for accommodating the heat exchange channel and an electrical connection region for accommodating a contact hole/pad pair. In this case, the aforementioned contact hole 110 is formed in the electrical connection region, and the trench 120 is formed in the heat exchange region. For example, there may be one or more such electrical connection regions. Arrangement examples of the contact hole 110 and the trench 120 in the second substrate 20 will be described with reference to FIGS. 3B and 3C. FIGS. 3B and 3C are, for example, both partial views of the upper surface of the semiconductor structure 100.

FIG. 3B is a schematic plan view of the semiconductor structure after the contact hole and the trench are formed in the method of fabricating a 3D IC module according to an embodiment of the present invention. In the example shown in FIG. 3B, a plurality of electrical connection regions I are arranged along two edges of the upper surface of the semiconductor structure 100, and a heat exchange region II extends across a central area of the upper surface of the semiconductor structure 100 and terminates at the other two edges. That is, all the electrical connection regions I are arranged beside the heat exchange region II. In the example of FIG. 3B, the trench 120 in the heat exchange region II is shaped like a grid. However, the present invention is not so limited. The shape of the trench 120 extending in the upper surface of the semiconductor structure 100 may be designed according to heat dissipation requirements. For example, it may be alternatively shaped like spirals or sinusoidal waves.

FIG. 3C is a schematic plan view of the semiconductor structure after the contact hole and the trench are formed in the method of fabricating a 3D IC module according to an embodiment of the present invention. In the example shown in FIG. 3C, instead of being concentrated along the edges of the upper surface of the semiconductor structure 100, contact holes 110, and hence respective conductive holes, pads and electrical connection regions I, are scattered. In this example, a heat exchange region II is arranged to avoid the electrical connection regions I. That is, the heat exchange region II interlaces with the electrical connection regions I across the upper surface of the semiconductor structure 100.

The present invention is not limited to the arrangements of contact holes 110 and the trench 120 in the upper surface of the semiconductor structure 100 shown in FIGS. 3B and 3C. In other embodiments, electrical connection regions I may be defined according to particular conductive hole and pad design requirements, and the rest of the upper surface may be taken as a heat exchange region II. The trench 120 may accordingly designed in the heat exchange region II. The trench 120 may account for a proportion of the total area of the upper surface of the semiconductor structure 100, which may be determined according to an area proportion of the heat exchange region II and heat dissipation requirements. For example, as shown, the proportion of the trench 120 in the total area of the upper surface of the semiconductor structure 100 may vary in the range of approximately 0.1% to 99%.

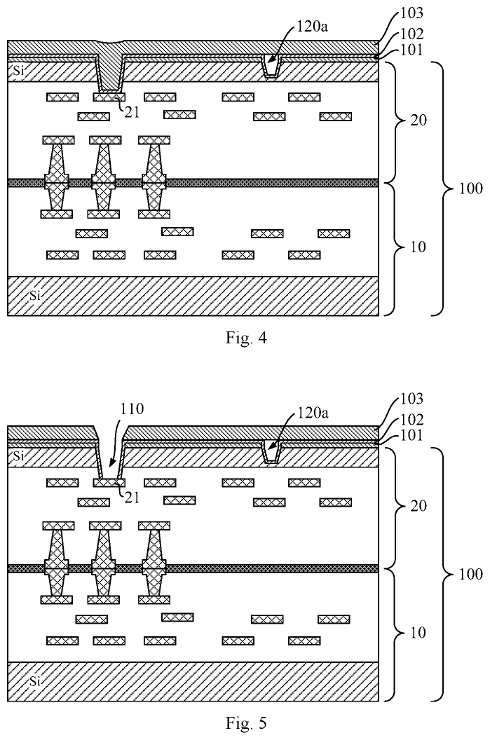

FIG. 4 is a schematic cross-sectional view of the semiconductor structure after a first passivation layer is formed in the method of fabricating a 3D IC module according to an embodiment of the present invention. Referring to FIG. 4, the method of fabricating a 3D IC module includes the step S3, a first passivation layer 103 is formed over the semiconductor structure 100, the first passivation layer 103 covers the upper surface of the topmost substrate and spans over and covers the trench 120, the first passivation layer 103 covers the trench 120 to define the heat exchange channel 120a.

In an optional embodiment, subsequent to the formation of the contact hole 110 and the trench 120 and prior to the formation of the first passivation layer 103, the method of fabricating a 3D IC module may further include the step of forming a surface cap layer 102 on the semiconductor structure 100. Referring to FIG. 4, the surface cap layer 102 conformally covers the upper surface of the semiconductor structure 100 having the contact hole 110 and the trench 120. That is, the surface cap layer also covers inner surfaces of the contact hole 110 and the trench 120. However, the surface cap layer 102 does not fill up the contact hole 110 and the trench 120. The surface cap layer 102 is formed to repair the surfaces of the contact hole 110 and trench 120. The protective layer 101 may be removed before the formation of the surface cap layer 102. In order to avoid adversely affecting the heat dissipation ability of the heat exchange channel, the surface cap layer 102 may have a small thickness (e.g., 1000 nm or smaller, such as between 10 nm and 100 nm, or another value that does not cause the trench 120 to be filled up). The surface cap layer 102 may be formed of a material selected from, among others, nitrogen-containing dielectrics, oxygen-containing dielectrics, boron nitrides, aluminum, aluminum-containing compounds, diamond-like carbon. Preferably, it is made of a material with good heat dissipation properties, such as a material with a coefficient of thermal conductivity of 30 W/m·K or higher. Further, in order to prevent device failure caused by ions diffusing from the surface cap layer 102, the material of the surface cap layer 102 is preferably chosen as one which has stable properties and does not tend to release diffusible ions.

The first passivation layer 103 may be formed over the semiconductor structure 100 after the formation of the surface cap layer 102. The first passivation layer 103 may be formed of silicon oxide, silicon nitride, silicon oxynitride or another material optionally using a chemical vapor deposition (CVD) process. In this embodiment, the CVD process may be controlled (e.g., by controlling the film formation rate of the CVD) so that the resultant first passivation layer 103 covers the upper surface of the second substrate 20 and spans over and covers the trench 120 so that a closed channel is formed, i.e., the heat exchange channel 120a according to the present embodiment. In other words, the first passivation layer 103 serves as a cap layer of the heat exchange channel 120a. During operation of the 3D IC module, a heat dissipation medium may be introduced to and circulate through the heat exchange channel, thereby taking away heat generated by the 3D IC module and enhancing heat dissipation. In an alternatively embodiment, the first passivation layer 103 may be formed in step S3 so as to fill up and cover the trench 120. In this case, release holes exposing the material of the first passivation layer in the trench may be subsequently formed by an etching process performed on the first passivation layer 103 (e.g., release holes may be formed by the etching process in step S4), and the material of the first passivation layer in the trench may be etched and removed through the release holes. After the etching process is complete, a dielectric material may be deposited to close the release holes. In this way, the heat exchange channel can also be formed along the trench.

FIG. 5 is a schematic cross-sectional view of the semiconductor structure after the first passivation layer is etched in the method of fabricating a 3D IC module according to an embodiment of the present invention. Referring to FIG. 5, the method of fabricating a 3D IC module includes the step S4, the first passivation layer 103 above and within the contact hole 110 is removed, and exposure of the specified metal layer 21 within the semiconductor structure 100 is caused through the contact hole 110. The first passivation layer 103 may be etched using any suitable etching method known in the art. If the specified metal layer 21 in the semiconductor structure 100 remains unexposed after the first passivation layer 103 above the bottom of the contact hole 110 has been removed, for example, due to the presence of the surface cap layer 102 and/or the dielectric layer of the semiconductor structure 100 thereon, another etching process may be carried out to remove the surface cap layer 102 and/or the dielectric layer at the bottom of the contact hole 110, thereby exposing the underlying specified metal layer 21. The exposed specified metal layer 21 can be used as a terminal functioning as an input and/or output interface between the semiconductor structure 100 and the outside world. During the etching process performing on the first passivation layer 103, a region around the contact hole 110 (encompassing the heat exchange channel 120a) may be covered (e.g., with photoresist) and protected from any possible damage.

In one embodiment, after the first passivation layer 103 is etched through, when the specified metal layer 21 remains unexposed due to the presence of the surface cap layer 102 and/or the dielectric layer of the semiconductor structure 100 thereon, instead of an etching process that proceeds downwardly from the entire bottom surface of the contact hole 110, a patterning process may be employed to remove the surface cap layer 102 and/or the dielectric layer under only a desired portion of the bottom surface of the contact hole 110 to expose the specified metal layer 21 under the contact hole 110.

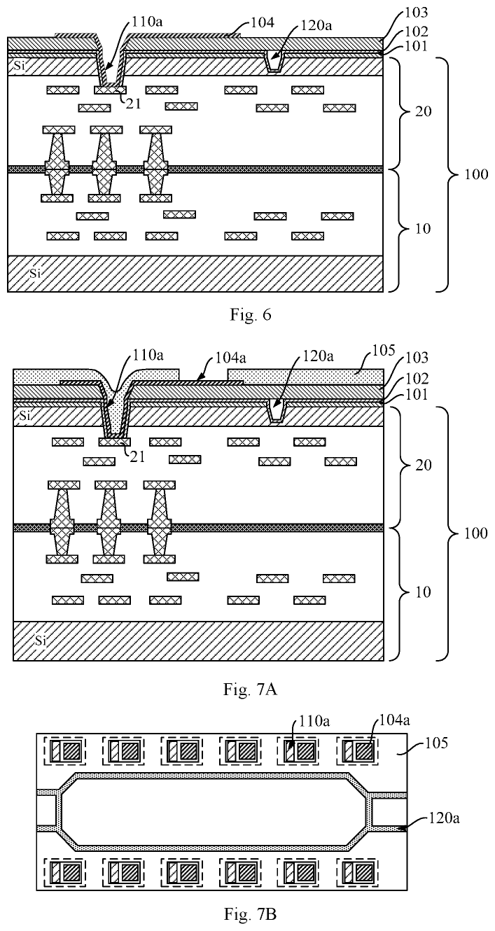

FIG. 6 is a schematic cross-sectional view of the semiconductor structure after a pad metal layer is formed in the method of fabricating a 3D IC module according to an embodiment of the present invention. Referring to FIG. 6, the method of fabricating a 3D IC module includes the step S5, a pad metal layer 104 is formed on the semiconductor structure, a portion of the pad metal layer 104 in the contact hole 110 is electrically connected to the specified metal layer 21, thereby forming a conductive hole 110a. That is, the conductive hole 110a is made up of the contact hole 110 and the pad metal layer 104 covering the contact hole 110. The conductive hole 110a is formed to electrically lead the specified metal layer 21 in the semiconductor structure 100 to above the first passivation layer 103.

The pad metal layer 104 may be formed of a material including one or more metals selected from, among others, aluminum, copper, nickel, zinc, tin, silver, gold, tungsten and magnesium or including an alloy of a metal such as aluminum, copper, nickel, zinc, tin, silver, gold, tungsten or magnesium. The pad metal layer 104 may be formed by physical vapor deposition (PVD), electroplating or electroless plating and subsequent patterning. For example, forming the pad metal layer 104 by electroplating may include: firs of all, forming a seed layer on inner surfaces of the contact hole 110 and an upper surface of the first passivation layer 103 by PVD or sputtering; then placing the semiconductor structure 100 with the seed layer in a plating tank of electroplating equipment and removing it therefrom after a predetermined period of time so that a plating layer is formed on the inner surfaces of the contact hole 110 and the upper surface of the first passivation layer 103; and after that, forming the pad metal layer 104 by removing unwanted portions of the plating and seed layers on the upper surface of the semiconductor structure 100 by a photolithography and etching process.

In an optional embodiment, the method of fabricating a 3D IC module may further include the step of forming a pad. FIG. 7A is a schematic cross-sectional view of the semiconductor structure after a second passivation layer and a pad are formed in the method of fabricating a 3D IC module according to an embodiment of the present invention. FIG. 7B is a schematic plan view of the semiconductor structure 100 after the second passivation layer and the pad are formed in the method of fabricating a 3D IC module according to an embodiment of the present invention. FIG. 7B may be considered as a schematic view corresponding to FIG. 3, which illustrates the semiconductor structure 100 after the pad 104a is formed. Referring to FIGS. 7A and 7B, in an embodiment, the method of fabricating a 3D IC module may further include: first forming a second passivation layer 105 on the semiconductor structure 100, the second passivation layer 105 covers the first passivation layer 103 and the pad metal layer 104; then etching and patterning the second passivation layer 105 to expose a portion of the pad metal layer 104. This portion of the pad metal layer 104 exposed from the second passivation layer 105 serves as the pad 104a.

The second passivation layer 105 is formed to protect the semiconductor structure 100 with the pad metal layer 104 being formed thereon, and as a result of patterning the second passivation layer 105, an opening is formed therein, which exposes the underlying pad metal layer 104. The location of the opening depends on the location of the portion of the pad metal layer 104 that serves as the pad 104a. In this embodiment, the portion of the pad metal layer 104 exposed from the second passivation layer 105 serves as the pad 104a. The pad 104a may be directly electrically connected to an external device. Alternatively, a solder bump (or solder ball) may be further formed on the pad 104a. In this case, the pad 104a may be electrically connected to an external device via the solder bump. The second passivation layer 105 may be formed of an oxide or nitride of silicon, such as silica, silicon nitride or silicon oxynitride, or a dielectric material such as magnesia, zirconia, alumina, lead zirconate titanate or gallium arsenide. The second passivation layer 105 may be alternatively formed of an organic material, such as a polyimide-based polymer, a propargyl ether polymer, a cyclobutane polymer, a perfluorocyclobutyl (PFCB) polymer, benzocyclobutene (BCB) or the like. The second passivation layer 105 may also be a stack of layers of different materials.

From the foregoing steps, the 3D IC module can be obtained. In the above method, during the formation of the conductive hole 110a in the semiconductor structure 100, the heat exchange channel 120a for enhancing heat dissipation is simultaneously formed, making the fabrication easier without causing a significant increase in cost. As the heat exchange channel 120a is routed on the top of the semiconductor structure 100 off the conductive hole 110a, it will not expand the size of the 3D IC module. During operation of the 3D IC module, a heat dissipation medium may be continuously supplied to and discharged from the heat exchange channel 120a to provide heat exchange. A device for supplying and recovering the heat dissipation medium may be integrated within the 3D IC module to provide an IC module with self-circulating heat exchange capabilities. Alternatively, the device may be a standalone device deployed around the 3D IC module.

Embodiments of the present invention further relate to a 3D IC module, which can be made using a method as defined above. Referring to FIGS. 1 to 7B, the 3D IC module includes a semiconductor structure 100 and a first passivation layer 103 on the semiconductor structure 100. The semiconductor structure 100 includes at least two substrates, which are stacked vertically one on another and electrically connected to one another. In a topmost one of the substrates in the semiconductor structure 100 is formed a conductive hole 110a for connection with a specified metal layer 21 therein. In the topmost substrate in the semiconductor structure 100 is also formed a trench 120 which is arranged to avoid the conductive hole 110a. The first passivation layer 103 spans over and covers the trench 120 to define a heat exchange channel 120a.

Each substrate in the semiconductor structure 100 may include a substrate layer, as well as fabricated on the basis of the substrate layer, semiconductor devices, interconnect layers, passivation layers and the like (referred to as a dielectric layer). In order to form the semiconductor structure 100, the substrates may be stacked together by gluing, bonding or otherwise. For example, they may be glued or bonded together with the substrate layers being adjacent to each other or opposite to each other (as shown in FIG. 2). Alternatively, the substrate layer of one substrate may be glued or bonded to the dielectric layer of another substrate. The conductive hole 110a and trench 120 in the topmost substrate may be formed in the substrate layer and/or the dielectric layer thereof. In the embodiment shown in FIG. 7A, the upper second substrate 20 includes a substrate layer (e.g., a silicon (Si) substrate layer) and an interconnect layer underlying the substrate layer, and the specified metal layer is situated within the interconnect layer. The contact hole extends through the substrate layer, with its bottom surface being located within the interconnect layer. For example, the bottom surface of the heat exchange channel 120a may be located within the substrate layer of the second substrate 20.

Specifically, the conductive hole 110a includes a contact hole 110 formed in the semiconductor structure 100 and a pad metal layer 104 covering inner surfaces of the contact hole 110. The pad metal layer 104 extends from the inside of the conductive hole 110a over an upper surface of the first passivation layer 103. The conductive hole 110a may extend through the first passivation layer 103. The 3D IC module may further include a second passivation layer 105 on the first passivation layer 103, the second passivation layer 105 defines and exposes a portion of the pad metal layer 104. The portion of the pad metal layer 104 exposed from the second passivation layer 105 serves as a pad 104a of the 3D IC module.

Continuing the example of FIG. 7A in which the semiconductor structure 100 includes the first substrate 10 and the second substrate 20, the second substrate 20 is the upper substrate in the semiconductor structure 100, the conductive hole 110a and the heat exchange channel 120a are formed in the second substrate 20 in the semiconductor structure 100. The conductive hole 110a and heat exchange channel 120a may be arranged in a plane defined by an upper surface of the semiconductor structure 100 (more precisely, the plane defined by the second substrate 20) in a manner determined according to particular design requirements. For example, in an embodiment, the upper surface of the semiconductor structure 100 defines a heat exchange region II for accommodating the heat exchange channel 120a and a plurality of electrical connection regions I each for accommodating a pair of a conductive hole 110a and a pad 104a (see FIGS. 3B and 3C). The heat exchange region II may interlace with the plurality of electrical connection regions I across the upper surface of the semiconductor structure 100. Alternatively, all the electrical connection regions I may be defined to surround the heat exchange region II. Depending on design requirements, the heat exchange channel 120a may assume any suitable shape, which facilitates heat dissipation while not affecting normal operation of the 3D IC module.

In order to enable introduction and recovery of a heat dissipation medium, the heat exchange channel 120a includes at least one heat dissipation medium inlet and at least one heat dissipation medium outlet. The heat dissipation medium can be introduced to the heat exchange channel through the heat dissipation medium inlet and discharged therefrom through the heat dissipation medium outlet. The heat dissipation medium inlet may be provided in a side face and/or the upper surface of the semiconductor structure, and the dissipation medium outlet may also be provided in a side face and/or the upper surface of the semiconductor structure.

As noted above in the description of the method of fabricating a 3D IC module, the trench 120 of the heat exchange channel 120a and the contact hole 110 of the conductive hole 110a may be formed in a single photolithography and etching process. It is not necessary for the specified metal layer 21 in the semiconductor structure 100 to be exposed in the trench 120. A width of the trench 120, i.e., a width of the heat exchange channel 120a may be in the range of approximately 0.3 μm to 100 μm. The distance between an upper surface of the topmost substrate (in this embodiment, an upper surface of a protective layer 101) and a bottom surface of the contact hole 110 is taken as a depth of the contact hole 110, and the distance between the upper surface of the topmost substrate and a bottom surface of the trench 120 is taken as a depth of the trench 120. The depth of the trench 120 may be in the range of approximately 5 μm to 10 μm. A depth of the heat exchange channel 120a may be smaller than or equal to the depth of the conductive hole 110a. The heat exchange channel 120a may account for a proportion of the total area of the upper surface of the semiconductor structure 100, which may be determined according to the size of an area available for its accommodation and heat dissipation requirements. In particular, the proportion may vary in the range of approximately 0.1% to 99%. In the upper surface of the semiconductor structure 100, the heat exchange channel 120a may be evenly distributed according to certain rules, or locally concentrated in one or more regions. For example, in an embodiment, the heat exchange channel may be more densely routed across some regions of the upper surface of the 3D IC module, which tend to cause an uneven heat distribution due to release of more heat there. In this way, excessive local heat build-up and uneven heat dissipation in the 3D IC module can be avoided.

In the 3D IC module of the present invention, the conductive hole 110a for connection with the internal specified metal layer 21 and the trench 120 arranged to avoid the conductive hole 110a are formed in the topmost substrate of the semiconductor structure 100. Moreover, the first passivation layer 103 spans over and covers the trench 120 to define the heat exchange channel 120a. During operation of 3D IC module, a heat dissipation medium may be caused to flow through the heat exchange channel 120a to facilitate heat dissipation. Thus, the 3D IC module has enhanced heat dissipation ability and is substantially immune from the problems of excessive heat build-up and uneven heat dissipation. This helps optimize performance and reliability of the 3D IC module.

It is to be noted that the embodiments disclosed herein are described in a progressive manner with the description of each embodiment focusing on its differences from others. Reference can be made between the embodiments for their identical or similar parts as appropriate.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A three-dimensional integrated circuit module, comprising a semiconductor structure and a first passivation layer on the semiconductor structure, the semiconductor structure comprising at least two substrates arranged in sequence from bottom to top, the substrates electrically interconnected, the semiconductor structure comprising at least one conductive hole located in a topmost one of the substrates and configured for connection with an internal specified metal layer, wherein in the topmost substrate in the semiconductor structure, a trench arranged to avoid the conductive hole is also formed, and the first passivation layer spans over and covers the trench to define a heat exchange channel.

2. The three-dimensional integrated circuit module of claim 1, wherein the heat exchange channel comprises at least one heat dissipation medium inlet and at least one heat dissipation medium outlet, a heat dissipation medium able to be introduced to the heat exchange channel through the heat dissipation medium inlet and discharged through the heat dissipation medium outlet, the heat dissipation medium inlet provided in a side face and/or an upper surface of the semiconductor structure, the heat dissipation medium outlet provided in a side face and/or the upper surface of the semiconductor structure.

3. The three-dimensional integrated circuit module of claim 1, wherein the topmost substrate comprises a substrate layer and an interconnect layer underlying the substrate layer, wherein the specified metal layer is arranged within the interconnect layer, and the conductive hole extends through the substrate layer with a bottom surface located within the interconnect layer.

4. The three-dimensional integrated circuit module of claim 3, wherein a bottom surface of the heat exchange channel is located within the substrate layer.

5. The three-dimensional integrated circuit module of claim 1, wherein the conductive hole comprises a pad metal layer, the pad metal layer extending from the inside of the contact hole over an upper surface of the first passivation layer.

6. The three-dimensional integrated circuit module of claim 5, further comprising a second passivation layer on the first passivation layer, wherein a portion of the pad metal layer is defined by and exposed from the second passivation layer, the portion of the pad metal layer exposed from the second passivation layer serving as a pad.

7. The three-dimensional integrated circuit module of claim 6, wherein the upper surface of the semiconductor structure comprises a heat exchange region for accommodating the heat exchange channel and a plurality of electrical connection regions for accommodating a set of conductive holes and pads, wherein the heat exchange region interlaces with the plurality of electrical connection regions, or the electrical connection regions are all disposed around the heat exchange region.

8. A method of fabricating a three-dimensional integrated circuit module, comprising:
providing a semiconductor structure, the semiconductor structure comprising at least two substrates arranged in sequence from bottom to top, the substrates electrically interconnected;
performing a downward etching process on a topmost one of the substrates to form at least one contact hole and a trench, which are both open upwardly, the trench arranged to avoid the contact hole, the contact hole configured to establish an electrical connection with a specified metal layer within the semiconductor structure, the trench configured to provide a heat exchange channel, wherein a depth of the contact hole is controlled so that the specified metal layer is exposed or not;
forming a first passivation layer on the semiconductor structure, which covers an upper surface of the topmost substrate and spans over and covers the trench, the first passivation layer covering the trench to define the heat exchange channel;
removing the first passivation layer above and within the contact hole and causing exposure of the specified metal layer through the contact hole; and
forming a pad metal layer on the semiconductor structure, a portion of the pad metal layer in the contact hole is electrically connected to the specified metal layer, thereby forming a conductive hole.

9. The method of claim 8, wherein the topmost substrate comprises a substrate layer and an interconnect layer underlying the substrate layer, wherein the specified metal layer is arranged within the interconnect layer, and the conductive hole extends through the substrate layer, a bottom surface located within the interconnect layer.

10. The method of claim 9, wherein a depth of the trench is smaller than or equal to the depth of the contact hole.

11. The method of claim 8, after the contact hole and the trench are formed and before the first passivation layer is formed, the method further comprising:
conformally forming a surface cap layer over the semiconductor structure, which covers inner surfaces of the contact hole and the trench but does not fill up the trench,
wherein after the first passivation layer is etched and before the pad metal layer is formed, the surface cap layer on a bottom surface of the contact hole is at least partially removed, thereby causing the exposure of the specified metal layer through the contact hole.

12. The method of claim 8, after the pad metal layer is formed, the method further comprising:
forming a second passivation layer over the semiconductor structure, the second passivation layer covering the first passivation layer and the pad metal layer, and
etching the second passivation layer to expose a portion of the pad metal layer, the portion of the pad metal layer exposed from the second passivation layer serving as a pad.
